(19) United States
(12) Patent Application Publication
(10) Pub. No.: US 2012/0161179 A1
(43) Pub. Date: Jun. 28, 2012

(54) LIGHT EMITTING DIODE PACKAGE

(75) Inventors: JUNG-HSI FANG, Hukou (TW); SHIH-YUAN HSU, Hukou (TW)

(73) Assignee: ADVANCED OPTOELECTRONIC TECHNOLOGY, INC., Hsinchu Hsien (TW)

(21) Appl. No.: 13/221,861

(22) Filed: Aug. 30, 2011

(30) Foreign Application Priority Data
Dec. 22, 2010 (CN) 201010595680.8

(51) Int. Cl. H01L 33/48; H01L 33/52

(52) U.S. Cl. 257/98; 257/100; 257/E33.059; 257/E33.056

(57) ABSTRACT

An LED package includes a base, an LED die arranged on the base, an encapsulation sealing the LED die, and a light wavelength converting layer arranged on a light path of the LED die. The light wavelength converting layer includes a plurality of first areas comprising red fluorescent powder, a plurality of second areas comprising green fluorescent powder and a plurality of third areas comprising blue fluorescent powder. The first, second and third areas are aligned along a first direction and a second direction perpendicular to the first direction. Each two neighboring areas on the first direction have different colors. Each two neighboring areas on the second direction also have different colors.

### BACKGROUND

1. Technical Field

The present disclosure generally relates to light emitting diode (LED) packages.

2. Description of Related Art

White-light LED illuminating devices had been developed due to their light weight and low power consumption. Red, green and blue (RGB) LED dies can be combined in a common package to generate white light by mixing the tri-chromatic lights. However, since the threshold voltages of the RGB light LED dies differ from each other, the required circuit to drive the LED dies is expensive and complicated.

Therefore, it is necessary to provide an LED package overcoming above shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a schematic, cross-sectional view of an LED package in accordance with a first embodiment of the present disclosure.

FIG. 2 is a schematic top-view of a light wavelength converting layer of the LED package of FIG. 1.

FIG. 3 is a schematic, cross-sectional view of an LED package in accordance with a second embodiment of the present disclosure.

FIG. 4 is a schematic top-view of a light wavelength converting layer of the LED package of FIG. 3.

### DETAILED DESCRIPTION

Reference will now be made to the drawings to describe the present LED package in detail.

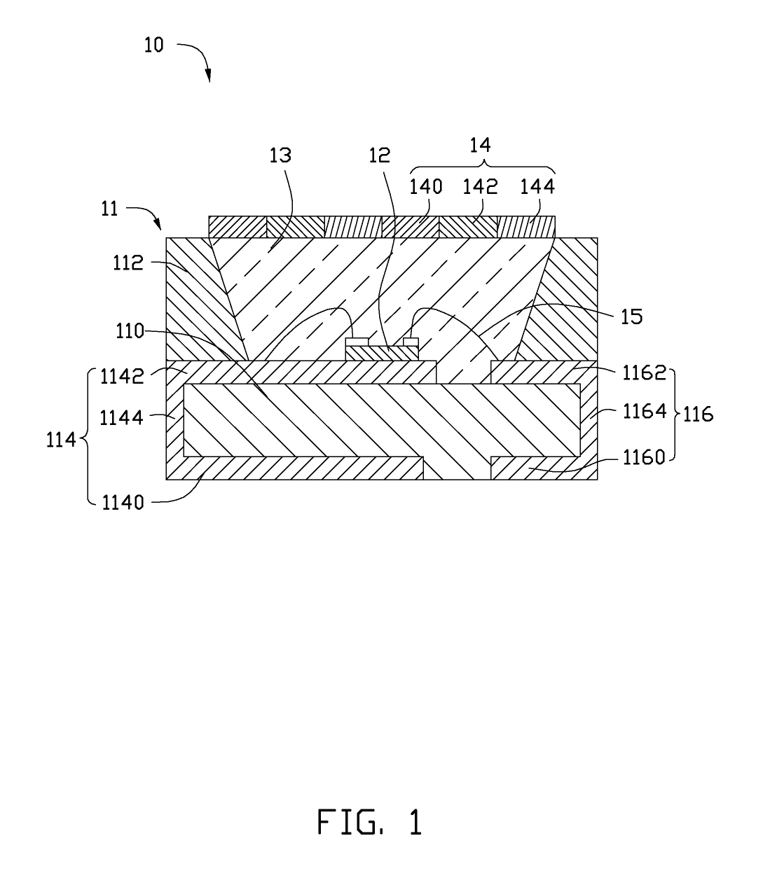

Referring to FIG. 1, an LED package 10 according to a first embodiment includes a base 11, an LED die 12, an encapsulation 13 and a light wavelength converting layer 14.

The base 11 includes a substrate 110, a reflective cup 112, a first electrode 114 and a second electrode 116. The first electrode 114 and the second electrode 116 are located on opposite lateral sides of the substrate 110. The reflective cup 112 is arranged on the first and second electrodes 114, 116.

The substrate 110 can be made integrally with the reflective cup 112. The substrate 110 can be made of silicon, plastic, ceramic or liquid crystal polymer. The reflective cup 112 can be made of liquid crystal polymer. The first electrode 114 and the second electrode 116 are made of metal. The first electrode 114 and the second electrode 116 are arranged at two side portions of the substrate 110. The first electrode 114 is opposite to and isolated from the second electrode 116. The first electrode 114 and the second electrode 116 each have a U-shaped configuration, and are positioned in a horizontal manner with openings thereof facing each other.

The first electrode 114 includes a contact portion 1140, a supporting portion 1142 and a connecting portion 1144. The second electrode 116 includes a contact portion 1160, a supporting portion 1162 and a connecting portion 1164.

The contact portions 1140, 1160 are configured at a bottom of the substrate 110. The supporting portions 1142, 1162 are configured at a top of the substrate 110 and contacting a bottom of the reflective cup 112. The connecting portions 1144, 1164 are respectively configured at lateral sidewalls of the substrate 110. The contact portions 1140, 1160 are for electrically connected with an external power supply. The supporting portions 1142, 1162 are for wired bonded to electrodes of the LED die 12. The connecting portion 1144 connects the contact portion 1140 with the supporting portion 1142. The connecting portion 1164 connects the contact portion 1160 with the supporting portion 1162.

In this embodiment, the contact portion 1140 is parallel to the supporting portion 1142, and the connecting portion 1144 is perpendicular to the contact portion 1140 and the supporting portion 1142. The contact portion 1160 is parallel to the supporting portion 1162, and the connecting portion 1164 is perpendicular to the contact portion 1160 and the supporting portion 1162.

The LED die 12 is arranged on the supporting portion 1142 and received in the reflective cup 112. Electrodes (not labeled) of the LED die 12 are respectively wire bonded to the supporting portions 1142, 1162 by wires 15. In this embodiment, the LED die 12 emits ultraviolet light. It is to be said that the LED die 12 can also be arranged on and electrically connected to the supporting portions 1142, 1162 by flip-chip.

The encapsulation 13 is made of light transmissive material. The encapsulation 13 fills the reflective cup 112 and seals the LED die 12. The encapsulation 13 further covers a part of the substrate 110 which are exposed between the first electrode 114 and the second electrode 116.

The light wavelength converting layer 14 is arranged on a top surface of the encapsulation 13 which is above and distant from the LED die 12. The light wavelength converting layer 14 includes a plurality of first areas 140 with red fluorescent powder, a plurality of second areas 142 with green fluorescent powder and a plurality of third areas 144 with blue fluorescent powder.

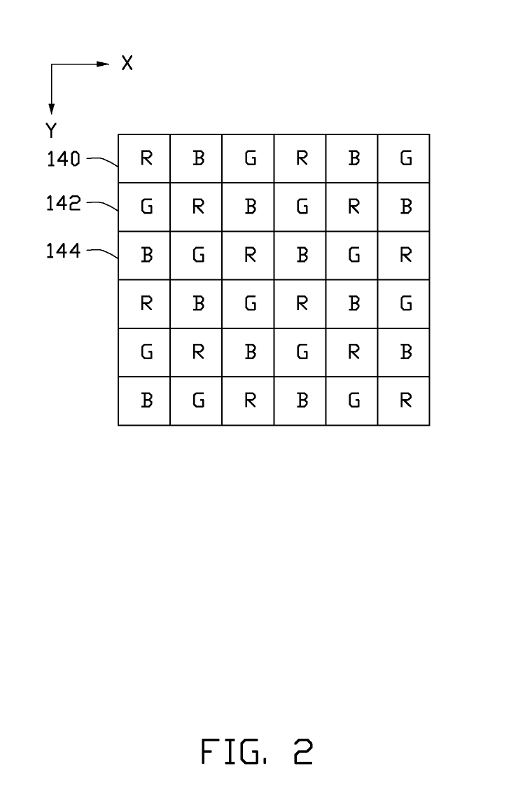

Referring to FIG. 2, the first areas 140, the second areas 142 and the third areas 144 are aligned along x direction and y direction. The y direction is perpendicular to the x direction. The label “R” stands for the first areas 140. The label “G” stands for the second area 142. The label “B” stands for the third areas 144.

In x direction, the first areas 140, the second area 142 and the third areas 144 on the horizontal lines are repeatedly arranged in predetermined sequences, and the predetermined sequences include a first sequence, a second sequence and a third sequence. The first sequence from left to right is sequentially the first area 140 (R), the third area 144 (B) and the second area 142 (G). The second sequence from left to right is sequentially the second area 142 (G), the first area 140 (R) and the third area 144 (B). The third sequence from left to right is sequentially the third area 144 (B), the second area 142 (G), the first area 140 (R). As such, each two neighboring areas along the x direction have different colors, and each two neighboring areas along the y direction also have different colors. The first areas 140, the second areas 142 and the third areas 144 are evenly arranged, and uniform white light is achieved accordingly.

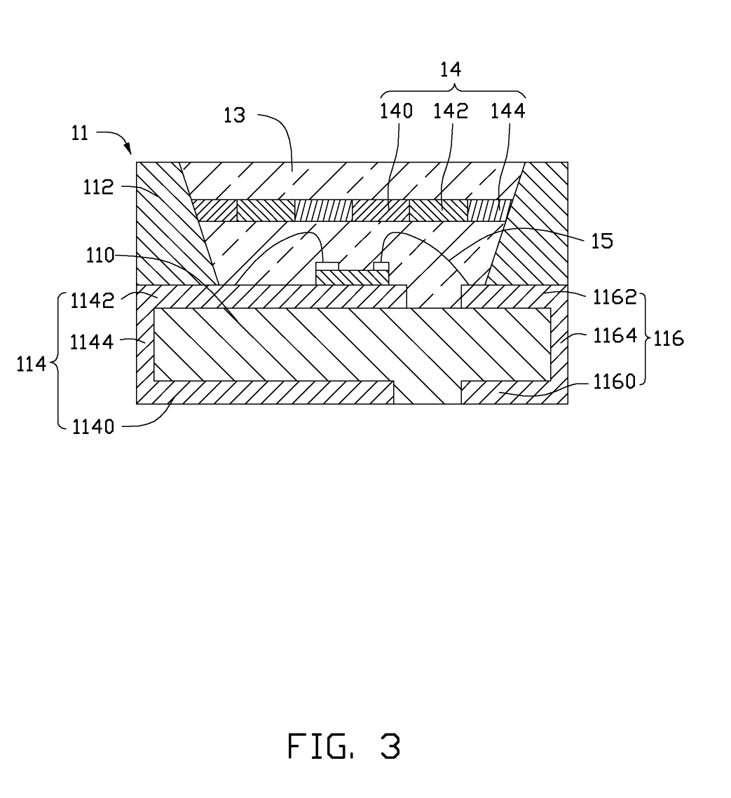

It is to be said that, the light wavelength converting layer 14 is not limited to be arranged on a top surface of the encapsulation 13, as long as the light wavelength converting layer 14 is located on light path of the LED die 12. Referring to FIG. 3, the light wavelength converting layer 14 can also be embedded in an interior of the encapsulation 13. As such, the encapsulation 13 is capable of protecting the light wavelength converting layer 14 from being destroyed by outer environment.

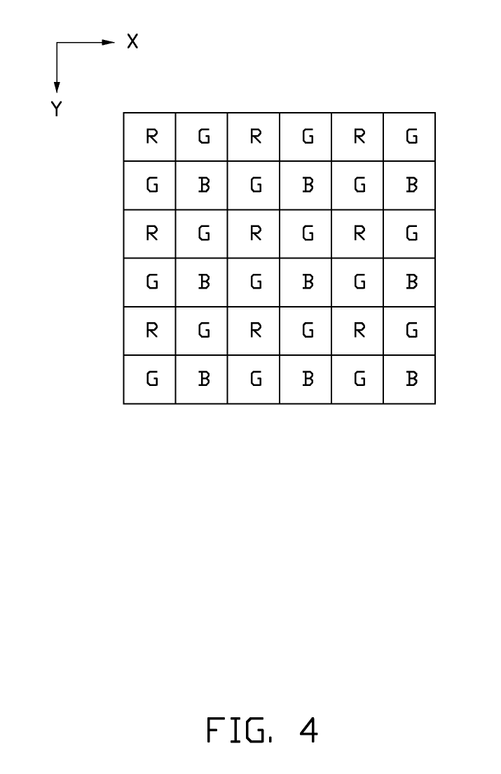

It is also to be said that, the alignment of the first areas 140, the second area 142 and the third areas 144 is not limited to above disclosed sequence. Referring to FIG. 4, the first areas 140, the second area 142 and the third areas 144 can also be arranged in another sequence. The first areas 140 (R) and the second areas 142 (G) are alternately aligned along a horizontal odd line in x direction and a vertical odd line in y direction. The second areas 142 (G) and the third areas 144 (B) are alternately aligned along a horizontal even line along x direction and a vertical even line along y direction.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An LED package comprising:
a base;
an LED die arranged on the base;
an encapsulation sealing the LED die;
a light wavelength converting layer arranged on a light path of the LED die, the light wavelength converting layer comprising a plurality of first areas comprising red fluorescent powder, a plurality of second areas comprising green fluorescent powder and a plurality of third areas comprising blue fluorescent powder, the fluorescent powders of each two neighboring areas along a first direction having different colors, the fluorescent powders of each two neighboring areas along a second direction perpendicular to the first direction also having different colors.

2. The LED package according claim 1, wherein the base comprises a substrate and a reflective cup arranged on the substrate, the LED die being received in the reflective cup.

3. The LED package according claim 2, wherein the encapsulation fills the reflective cup and partly covers the substrate.

4. The LED package according claim 1, wherein the LED die emits ultraviolet light.

5. The LED package according claim 1, wherein the light wavelength converting layer is embedded in an interior of the encapsulation.

6. The LED package according claim 1, wherein the light wavelength converting layer is configured on a surface of the encapsulation which is above and distant from the LED die.

7. An LED package comprising:
a base;
an LED die arranged on the base;
an encapsulation sealing the LED die;
a light wavelength converting layer arranged on a light path of the LED die, the light wavelength converting layer comprising a plurality of red fluorescent areas, a plurality of green fluorescent areas and a plurality of blue fluorescent areas, the red fluorescent areas, the green fluorescent areas and the blue fluorescent areas being aligned along a first direction and a second direction, the second direction being perpendicular to the first direction, each two neighboring fluorescent areas along the first direction having different colors, each two neighboring fluorescent areas along the second direction also having different colors.
